(19) United States
(12) Patent Application Publication
(10) Pub. No.: US 2011/0240089 A1
(43) Pub. Date: Oct. 6, 2011

(54) PHOTOVOLTAIC MODULE WITH BACK BOX AND ASSEMBLY METHOD THEREFOR

(75) Inventor: Gerald R. WOOTTON, Cambridge (CA)

(73) Assignee: ATS Automation Tooling Systems Inc., Cambridge (CA)

(21) Appl. No.: 13/076,214

(22) Filed: Mar. 30, 2011

Related U.S. Application Data
(60) Provisional application No. 61/319,421, filed on Mar. 31, 2010.

(51) Int. Cl. H01L 31/05; H01R 43/00

(52) U.S. Cl. 136/244; 29/825

(57) ABSTRACT

A method for assembling a photovoltaic module with an integrated back box including: applying links to a back side of a photovoltaic module subassembly; forming a connection between the links and an internal bus element of the photovoltaic sub-assembly; connecting external lead wires to the links; applying a housing over the links and a portion of the lead wires; and applying potting material to fill any cavities between the back of photovoltaic module, the lead wires and the housing. A photovoltaic module with integrated back box manufactured according to this method.

### RELATED APPLICATIONS

This application claims priority to U.S. Provisional Patent Application 61/319,421 filed Mar. 31, 2010, which is hereby incorporated by reference.

### FIELD

The present document relates generally to solar (photovoltaic) panel construction. More particularly, the present document relates to a photovoltaic module with back box and an assembly method therefor.

### BACKGROUND

With continuing emphasis placed on renewable energy sources, photovoltaic energy has become increasingly popular. Typically, photovoltaic cells are arranged in a panel or module subassembly and the panel is then provided with a junction box or “back box” on the rear of the panel to provide a complete photovoltaic module. The back box assembly allows connection of the module to other modules, electrical systems or the like.

Photovoltaic modules are intended to be used for a long lifetime, for example, 20-years or more. As such, one function of the back box assembly is to provide a moisture seal to prevent damage to the photovoltaic module. This is particularly the case for thin film modules where the cells are particularly sensitive to moisture; however, modules of various types have potential weaknesses including the tendency of commonly used laminating films to produce acidic compounds that are activated by water, the tendency of polymer back-sheet layers to break-down and delaminate due to hygroscopic properties and the tendency of some glass to give up free sodium ions. An additional consideration in colder climates is the crystallization of trapped moisture at extremely low temperatures, which can induce significant, possibly damaging, mechanical stress. One pathway for moisture ingress is provided by the lead wires within the back box assembly, which are commonly made of stranded wire; consequently, water that infiltrates into connectors or other external wiring can be drawn through the leads by capillary action, which must be prevented by sealing or interrupting this path. It is typical for a one or two stage seal to be used for the required sealing.

Typical back box designs may be quite large and protrude beyond the module framing in order to allow tool access to make the connection to between the lead wires and a bus element of the photovoltaic module. Because of the need for tool access, back boxes usually require a separate lid to be applied after most of the other assembly operations are complete. Conventional back boxes are also typically supplied with lead wires pre-installed and can be difficult to reconfigure. Often various configurations of lead wire, including various lead lengths, wire gage, insulation types etc. need to be stocked.

### SUMMARY

As such, there is a need for an improved photovoltaic module (PV) with back box and an improved method of assembling photovoltaic modules that is intended to overcome at least some of the limitations of existing photovoltaic modules and methods.

In one aspect, there is provided a method for assembling a photovoltaic module with integrated back box comprising: applying links to the back of the PV module sub-assembly in order to form a connection with its internal bus element; applying sealant over the links; connecting external leads to the links; applying the housing over the link and a portion of the leads; and applying potting material to fill the cavities between the module back sheet, sealant, leads and the housing. Optionally, diodes or other devices may be incorporated while forming the back box onto the PV module sub-assembly.

In some cases the housings may be fed on a tape baker or may be feed using a conventional tape and reel feeding system. In other cases, the housings may be fed on an insert tape where the insert tape includes an insert that is part of the housing.

According to an aspect herein, there is provided a photovoltaic module with integrated back box including: a photovoltaic module subassembly that includes a back sheet, a cut-out in the back sheet, and a bus element exposed via the cut-out; a link that is bonded to the bus element and extends external to the cut-out; a lead wire bonded to the link; and a housing attached to the back sheet and configured to cover the cut-out, bus element, and link wherein the lead wire extends from inside the housing to outside the housing and wherein the housing is attached to the back sheet after the lead wire is bonded to the link.

In a particular case, the link connecting the bus element and the wire lead is a flexible link. In this case, the link may extend within the housing or have larger dimensions than required to complete the link in order to provide heat dissipation.

In another particular case, the photovoltaic module may further include a sealant for sealing the cut-out.

In still another particular case, the photovoltaic module may further include support members provided in the housing to support the housing and provide additional mounting strength to the housing. In some cases, the photovoltaic module may also or alternatively include support members provided in the housing to support the wire lead and brace the wire lead against external forces.

In most cases, the photovoltaic module will include some form of potting material or other material provided in the housing to seal and protect the elements inside the housing. In some cases, the potting may be provided to the housing in advance of attaching the housing to the back sheet.

According to another aspect herein, there is provided a method for assembling a photovoltaic module with integrated back box including: receiving a photovoltaic module subassembly, the photovoltaic module subassembly that includes a back sheet, a cut-out in the back sheet, and a bus element exposed via the cut-out; connecting a link to the bus element such that the link extends external to the cut-out; attaching a wire lead to the link; and attaching a housing to the back sheet such that the housing covers the cut-out, the link and the bus element, wherein the wire lead extends from inside the housing to outside the housing and wherein the housing is attached to the back sheet after the wire lead is bonded to the link.

In a particular case, the method may further include: applying a sealant to cover the cut-out and the bus element prior to attaching the wire lead to the link.

In another particular case, the method may further include applying a potting material to fill any cavity between the back sheet and the housing.

In another particular case, the method may further include applying a sealant around the housing after attaching the housing to the back sheet.

In another particular case, the method may further include attaching a diode to the bus element prior to attaching the housing to the back sheet.

In yet another particular case, the attaching the housing to the back sheet may include applying an adhesive tape to the housing and pressing the housing onto the back sheet.

In still yet another particular case, the method may further include applying a sealant around a point where the wire lead extends outside the housing.

Conventional junction boxes are not particularly suitable for high-speed automation, can have high material costs and can have a higher profile than would be preferred for packing density of complete panels. The embodiments herein are intended to provide a back box that is comprised of components that are suitable for bulk feeding and are automation friendly. Further, they are intended to provide a junction box with reduced material costs and increased versatility through recipe driven product configuration. Finally, they are intended to provide a back box with a reduced profile of the overall solar panel with the back box to allow for greater packing density in shipping containers.

Other aspects and features will become apparent to those ordinarily skilled in the art upon review of the following description of specific embodiments in conjunction with the accompanying figures.

### BRIEF DESCRIPTION OF FIGURES

Embodiments will now be described, by way of example only, with reference to the attached Figures, wherein:

FIG. 1A is a back view of a typical framed photovoltaic module;

FIG. 1B is a side view of the framed photovoltaic module of FIG. 1A;

FIG. 2A is a back view of a typical frameless photovoltaic module with junction box;

FIG. 2B is a side view of the typical frameless photovoltaic module of FIG. 2A;

FIG. 3A is a back view of a photovoltaic module with multiple lead wire entries;

FIG. 3B is a side view of a photovoltaic module with multiple lead wire entries;

FIG. 4A is a back view of a photovoltaic module laminate sub-assembly arrangement;

FIG. 4B is a back view of a photovoltaic module with a second typical sub-assembly arrangement;

FIG. 4C is a back view of a photovoltaic module with a third typical sub-assembly arrangement;

FIG. 5A illustrates a back view of a link placement on a photovoltaic module according to one embodiment herein;

FIG. 5B is a cross sectional view of the link placement on the photovoltaic module of FIG. 5A;

FIGS. 6A, 6B, 6C and 6D illustrate a back view of alternative link placements on a photovoltaic module;

FIG. 7A illustrates a back view of a linked placement with a partly formed link on a photovoltaic module;

FIG. 7B is a cross sectional view of the linked placement with a partly formed link of FIG. 7A;

FIG. 8A illustrates a back view of a surface mount diode connected to links;

FIG. 8B illustrates a back view of an axial diode placement;

FIG. 9A illustrates a back view of an alternative diode placement;

FIG. 9B illustrates a back view of another alternative diode placement;

FIG. 10A illustrates a back view of an encapsulation example on a photovoltaic module;

FIG. 10B is a cross sectional view of the encapsulation example of FIG. 10A;

FIG. 11A is a back view of a lead attachment according to an embodiment;

FIG. 11B is a back view of a lead attachment with link formed over lead according to another embodiment;

FIG. 12A is a back view of a convoluted lead attachment according to an embodiment;

FIG. 12B is a back view of a convoluted lead attachment according to another embodiment;

FIG. 13A illustrates a back view of an assembly of a photovoltaic module back box with a diode applied outside the sealant;

FIG. 13B illustrates a back view of an alternative assembly of a photovoltaic module back box with a diode applied outside the sealant;

FIG. 14A illustrates a back view of a completed back box on a photovoltaic module;

FIG. 14B is a cross sectional view of the completed back box of FIG. 14A;

FIG. 15A is a cross section of a completed back box with the use of an additional edge seal applied prior to the housing;

FIG. 15B is a cross section of the completed back box with the use of an additional edge seal applied after the housing;

FIG. 15C is a cross section of the completed back box with the use of a bonding tape seal;

FIG. 16A illustrates a side view of a completed back box according to an embodiment of the photovoltaic module;

FIG. 16B illustrates a cross sectional view of a completed back box of FIG. 16A cut at line B;

FIG. 17A illustrates a back view of the photovoltaic module subassembly laminate prior to back box assembly according to an embodiment of the method of assembling a photovoltaic module back box;

FIG. 17B is a cross section view of the input according to FIG. 17A;

FIG. 18A illustrates the link attachment according to an embodiment of the method of assembling a photovoltaic module back box;

FIG. 18B is a cross section view of the link attachment of FIG. 18A;

FIG. 19A illustrates the diode attachment according to an embodiment of the method of assembling a photovoltaic module back box;

FIG. 19B is a cross section view of the diode attachment of FIG. 19A;

FIG. 20A illustrates the application of sealant according to an embodiment of the method of assembling a photovoltaic module back box;

FIG. 20B is a cross sectional view of the application of sealant of FIG. 20A;

FIG. 21A illustrates the placing of one or more lead wires;

FIG. 21B is a cross sectional view of the placing of one or more lead wires of FIG. 21A;

FIG. 22A illustrates the addition of a housing;

FIG. 22B is a cross sectional view of the addition of the housing of FIG. 22A;

FIG. 23A illustrates an initial state of a photovoltaic module laminate subassembly prior to back box assembly according to an embodiment of the method of assembling a photovoltaic module back box;

FIG. 23B is a cross section view of the input of FIG. 23A;

FIG. 24A illustrates link attachment;

FIG. 24B is a cross section view of the link attachment of FIG. 24A;

FIG. 25A illustrates a diode attachment;

FIG. 25B is a cross section view of the diode of FIG. 25A;

FIG. 26A illustrates application of sealant;

FIG. 26B is a cross sectional view of the application of sealant of FIG. 26A;

FIG. 27A illustrates the placing of one or more lead wires according to an embodiment of the method of assembling a photovoltaic module back box;

FIG. 27B is a cross sectional view of the placing of one or more lead wires of FIG. 27A;

FIG. 28A illustrates the addition of a housing; and

FIG. 28B is a cross sectional view of the addition of the housing of FIG. 28A.

### DETAILED DESCRIPTION

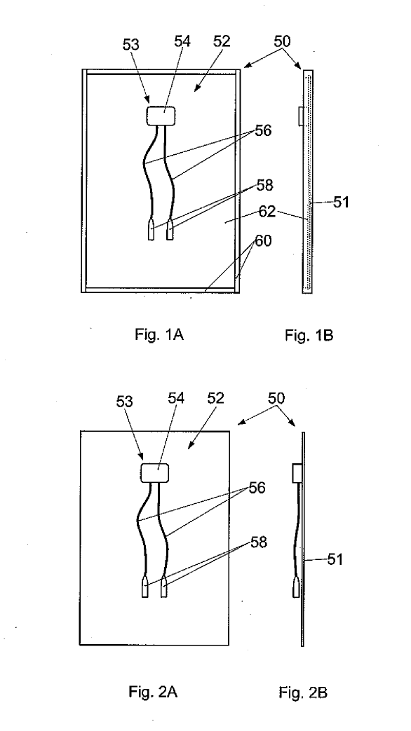

A typical flat-plate photovoltaic module consists of a transparent sheet or film material to which a matrix of solar cells has been applied (laminated or deposited) with internal connections among the matrix of solar cells completed by bus elements or bus wires, all of which is covered by a back sheet. Bus wires are typically flat ribbon wires and are exposed through an opening or openings in the back sheet for the purpose of forming external connections. Conventional back boxes are sub-assemblies having leads previously attached. The back box is affixed to the back sheet to provide a protective enclosure for the connections and for mechanical retention for the leads. Connections to the bus element are often formed after the back box has been attached to the back sheet. If protective diodes are required, they may also be incorporated into the back box assembly. These protective diodes may include bypass diodes providing reverse bias protection for strings of cells and blocking diodes preventing back-feed of the module. The assembly of the back box is generally completed with the possible addition of sealants or potting material and finished with the application of a lid or housing attached to the back box. Two stage seals are common as these seals can be optimized for effectiveness as a moisture barrier and as a vapor barrier. A further perimeter seal or gasket may also be used, particularly to provide mechanical retention if the primary sealants are insufficient for this purpose. Typical photovoltaic modules and junction box or back box layouts are illustrated in FIGS. 1 to 4.

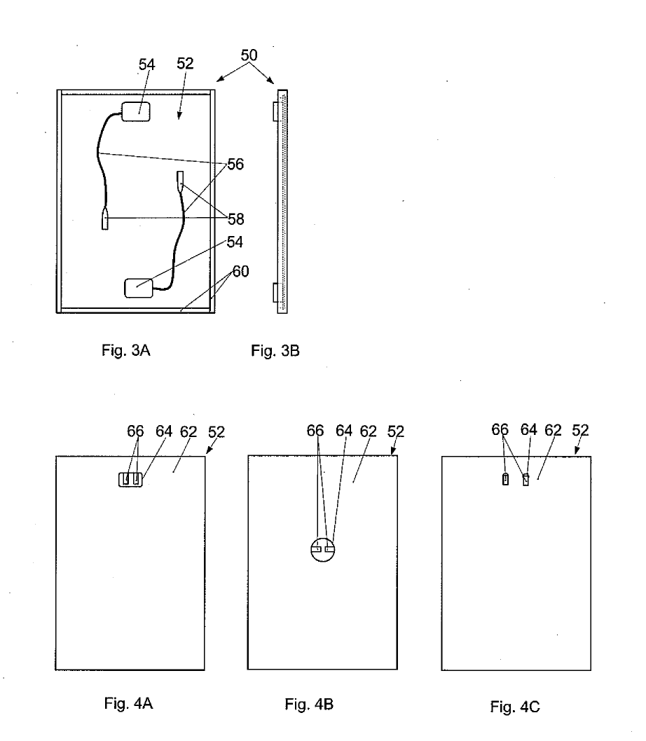

A photovoltaic module (50) may either be framed (as in FIGS. 1A and 1B), in which a frame (60) runs the perimeter of the photovoltaic module (50), or frameless as in FIGS. 2A and 2B. A photovoltaic module laminate subassembly (52) typically includes a window (51), for example, a transparent sheet of glass, acrylic, polycarbonate, etc. or polymer film or the like, photovoltaic cell array (not shown), bus element (66) (shown only in FIGS. 4A to 4C) and back sheet (62) through which portions of the bus element (66) are exposed. Bus element (66) may be understood to be the bussing of the photovoltaic module, which includes bus wires, bus connectors, bus terminals, bus tape or other element that may provide the required bussing to the photovoltaic module. In conventional photovoltaic modules, a back box subassembly (53) is affixed to the photovoltaic module subassembly. The back box subassembly (53) includes a back box (54) and lead wires (56), also referred to as wire leads, which extend through the back box (54). The lead wires (56) of the back box subassembly (53) are connected to the bus element (66), often via terminals inside the back box (see FIGS. 4A to 4C). Typically the lead wires are attached by soldering, clamping, welding or the like, within the back box (54). The lead wires (56) extend out of the back box (54) and connectors (58) may be attached at the end of the lead wires (56), if required, for further connection to other modules or electrical systems. As shown in FIGS. 3A and 3B, the photovoltaic module (50) may include multiple back boxes (54). As shown in FIGS. 1B and 3B, the back box (54) typically protrudes beyond the module framing.

FIGS. 4A, 4B and 4C illustrate various module laminate subassemblies (52) prior to the attachment of the back box. The photovoltaic module subassemblies (52) generally contain at least one opening or cut-out (64) in the back sheet (62), which expose the bus element (66) or through which the bus element can be accessed. The back box assembly (53) would then be placed over the cut-out (64) and fastened in place. The lead wires (56) inside the back box (54) would then be attached to the bus element (66). As shown in FIGS. 4A and 4B, bus element (66) may be exposed through a cut-out (64), such as a hole in the back sheet (62). Bus element (66) may alternatively be pulled through a cut-out (64) such as slits in the back sheet (62) as shown in FIG. 4C. Back boxes may be supplied with diodes already installed or they may be added at the time of assembly. Additional sealant and/or potting material may be dispensed into the back box. Finally, a lid is generally applied to complete the enclosure.

The following description and figures illustrate an alternative photovoltaic module and method for assembling a photovoltaic module in which a back box is assembled in place on the photovoltaic module subassembly rather than attaching a partially assembled back box subassembly to a photovoltaic module subassembly. In particular, the photovoltaic module and method involves the use of a link between the bus element of the photovoltaic module subassembly and lead lines, which extend through the back box.

In embodiments herein, due to the assembly sequence, the back box is a full enclosure that does not require a working opening, and consequently a lid or cover or other sealant, in order to be useful. This arrangement is possible because the back box enclosure is applied after forming the internal connections as a part of the PV module assembly rather than before making the internal connections, as is the case with conventional junction box connections.

The back box is sealed to the PV module subassembly by an optional exterior seal or adhesive bead or tape attached to the back box. Various types of sealing are described below. Further, lead wires may optionally have a connector installed on the free end. One or more back boxes may be assembled onto a photovoltaic module depending on configuration.

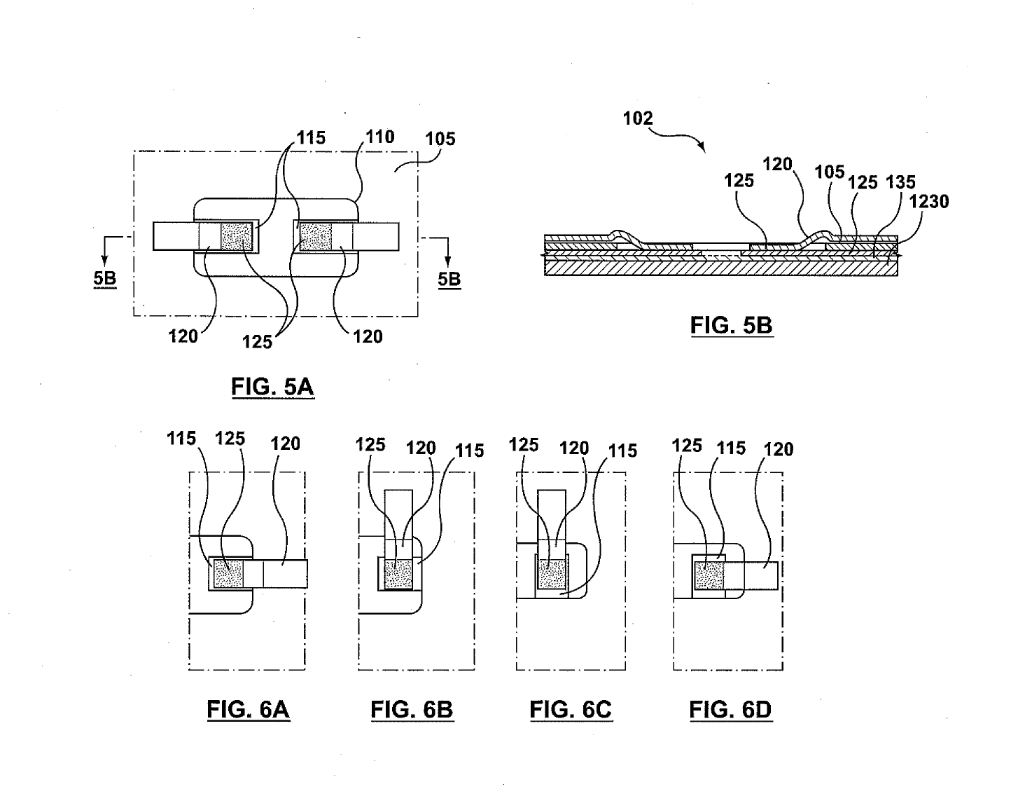

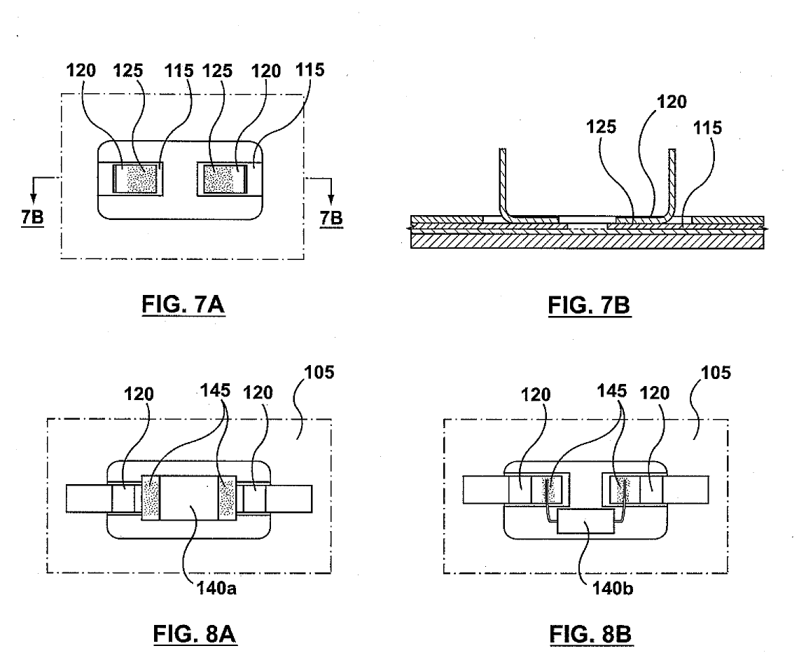

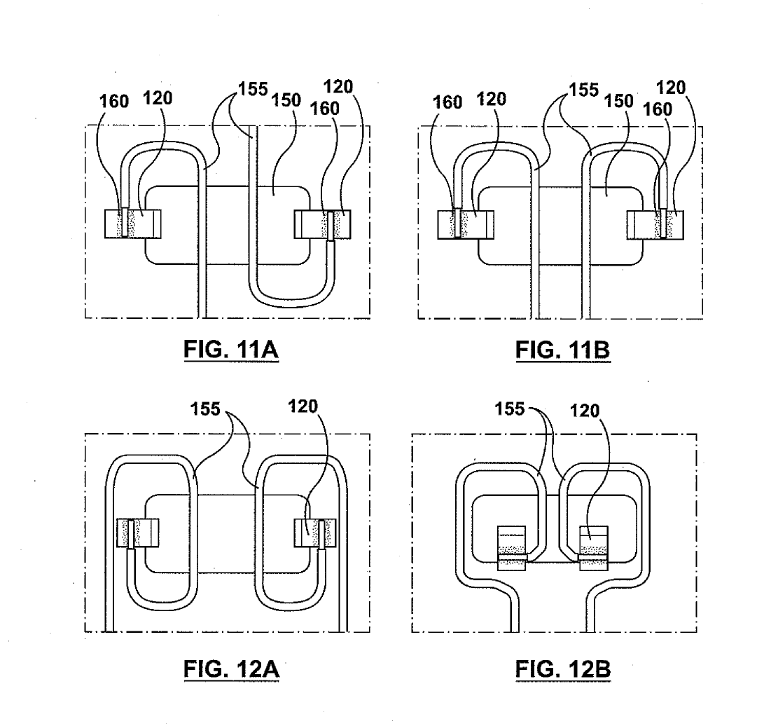

FIGS. 5 to 7 show a cut-out (110) in a back sheet (105) and links (120) between the bus element (115) and wire leads (155, shown in FIG. 11) to illustrate various placement alternatives for the links (120). In FIGS. 5 and 6 the links (120) are fully formed and in FIGS. 7A and 7B the links (120) are partially formed and the forming would be completed later in the assembly process. The cut-out (110) allows access to the bus element (115). The links (120) are attached to the bus element (115) by an electrically conductive connection, for example, solder (125) or may be attached through welding or conductive adhesive. The cross-sectional views in FIGS. 5B and 7B further illustrate a window/superstrate (130) and solar cell matrix (135) of the photovoltaic module subassembly (102). FIGS. 6A to 6D illustrate various options for placement of the links (120), which allow for continuation or redirection of the bus element (115) as needed.

The links (120) are preferably flexible in order to provide compliance to accommodate thermal expansion and contraction. The links (120) may also be formed with extra convolutions to improve compliance to thermal expansion and/or provide greater surface area for sealant contact. Using a separate link (120) to connect the bus element (115) to the wire leads (not shown) not only obviates the need to perform a wire pulling operation, where bus element (115) are pulled through the back sheet (105) to accomplish back box connections, but may also facilitate automated bus placements. The use of links (120) may also facilitate flexible assembly with multiple lead entry options independent of underlying module bus element arrangements since lead wires may assume various orientations relative to the module bus element without complication. Various examples are shown in FIGS. 6A to 6D.

The links (120) may be formed from ribbon wire, which may be soldered to the bus element (115) with minimal thermal input due to the low thermal mass of the links (120). This assists in avoiding the extra thermal stress that would generally result from directly attaching lead wires. The links (120) may alternatively be formed from solid wire or braided wire but these materials may be less advantageous. Stranded or braided wire may have voids in the wire that may need to be filled with solder and/or sealant in order to achieve an effective seal.

During assembly, the links (120) may be formed and trimmed from bulk (reel) fed ribbon wire stock by assembly automation tooling (not shown). Alternatively, the links (120) may be partially formed and attached leaving additional access for sealant application and then may be further formed by the assembly automation tooling following sealant dispensing and setting or curing. In some cases, this may also facilitate axial or bypass diode installation by providing greater access for placing and attaching a diode. As a further alternative, the links (120) may be formed by lifting existing bus element (115) and forming and trimming the bus element (115) in place in one or two process steps.

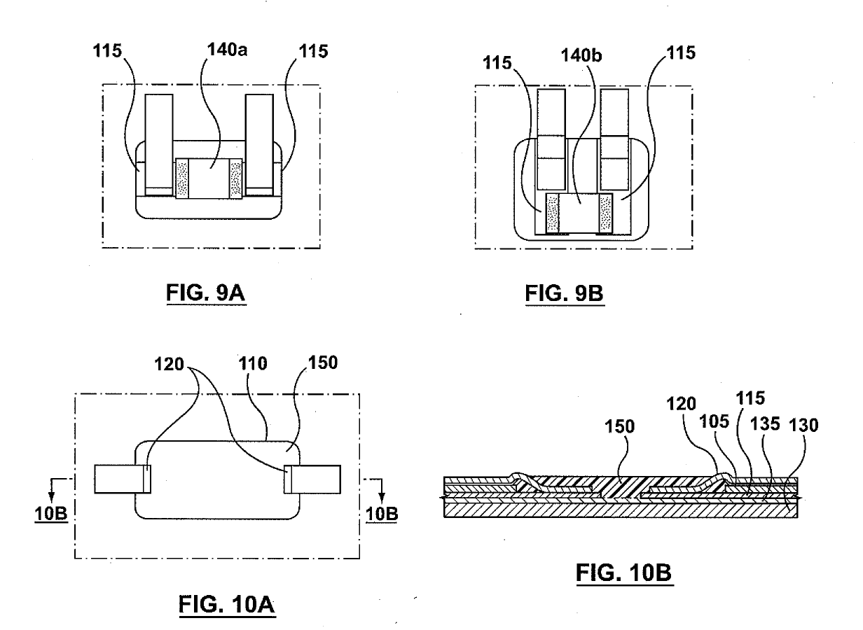

As noted above, the photovoltaic module may also comprise one or more diodes. FIG. 8A illustrates an embodiment including a surface mount diode (140a), which is shown mounted over the links (120), while FIG. 8B illustrates an alternative embodiment with an axial diode (140b). FIGS. 9A and 9B illustrates further alternatives for the placement of a diode where the diode (140) is mounted directly over the bus element (115) separate from the link attachment and may be between the links (120) as in FIG. 9A or outside of them as in FIG. 9B. The diodes (140) may be attached to the link (120) or bus element (115) by an electrical connection such as solder (145) or conductive adhesive.

It will be understood that one or more diodes may be placed and attached in place to the bus element (115) or placed and attached to the links (120). In assembly, the diodes (140) may be bulk (tape) fed axial diodes or surface mount diodes, which may be trimmed and formed by the automation tooling. The diodes (140) may be placed in close contact with the substrate in order to provide for heat sinking of the diode. Alternatively, the diodes may be placed outside of a sealant (see FIG. 10) and may rely on potting material to provide heat sinking. In a further alternative, the links (120) may be widened and/or extended to provide an additional heat sink for the diodes (140).

FIGS. 10A and 10B illustrate the encapsulation of the cut-out (110) with a sealant (150). The sealant (150) is intended to provide a hermetic seal for the cut-out (110) in the back sheet (105) and a hermetic feed through for the links (120). The sealant (150) may be a reactive material, which may form strong bonds with the back sheet (105) and metal surfaces. As shown in FIGS. 10A and 10B, the sealant (150) may be filled into the cut-out (110), coating the exposed portions of the window/superstrate (130), cell matrix (135), bus element (115) and links (120) as well as the edges of the cut-out (110).

FIGS. 11 and 12 illustrate various configurations of the attachment of lead wires (155) to the links (120). During assembly, the lead wires (155) may be bulk (reel) fed, trimmed, formed, cut to length and soldered in place by the automation tooling. In some cases the lead wires (155) may be formed into a convoluted shape, as illustrated in FIGS. 12A and 12B, in order to facilitate retention of the lead wires (155) if the lead wires (155) are subject to external forces. FIG. 11A shows the lead wires (155) placed onto the links, while FIG. 11B illustrates an alternative where the links (120) are formed over the lead wires (155). FIG. 12A illustrates links (120) having an in-line configuration, while FIG. 12B illustrates a parallel configuration. The lead wires (155) are attached by an electrical connection, such as solder (160).

The links (120) are intended to fulfill a further purpose by facilitating the formation of a seal for the cut-out (110). The transition between the lead wires (155) and the links (120) helps to prevent the lead wires (155) from being able to wick moisture into the interior of the cut-out (110) as can happen when the lead wires (155) are connected directly to the bus element (115).

The lead wires (155) may optionally be tacked to the back sheet (105) using a temporary peelable or washable adhesive (not shown) to prevent movement during subsequent assembly processes. The adhesive may be particularly useful in a high-speed production system where individual processes are staged at separate stations with product transport between stations. Producing lead wires (155) from raw materials may provide greater versatility in product configuration and may also allow lower inventory since the configuration of the lead wires (155), length, color, wire gage, insulation rating etc can be determined at time of assembly and the lead wire configuration and housing configuration can vary independently. Lead wires (155) may be made of various materials as long as the requisite conductivity is achieved. Lead wires (155) may be installed without connectors in order to reduce cost, although connectors may be attached by automation tooling as an additional process step. The placement of lead wires (155) in the assembly process is intended to improve on the conventional approach of stocking previously assembled back boxes with lead wires attached in all of the required configurations necessitated by the module manufacturers' product mix.

As lead wires (155) are fed, trimmed, formed and cut to length by programmable automation tooling, the lead wires (155) may have recipe driven configurations. The lead wires (155) may be formed into more than one alternative shape facilitating configurable polarity and/or lead exit directions. Preferred shapes may include J-bends, S-bends and other forms that facilitate mechanical retention of the lead wires (155), as described in further detail below.

Optionally, after attachment, exposed lead wires (155) may be treated with a low-viscosity conformal coater, which may reduce wire wicking of the lead wires.

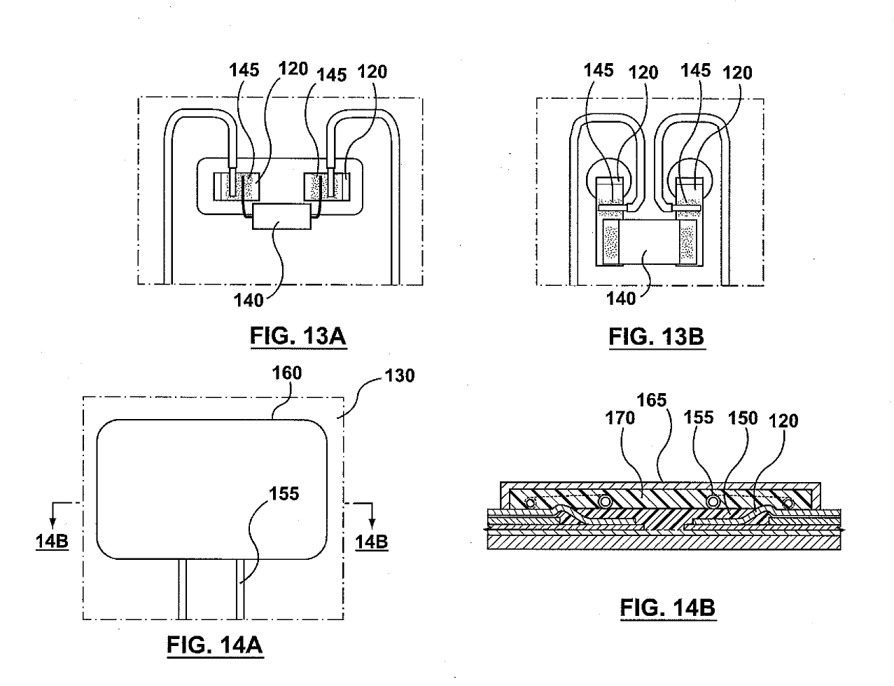

As noted above, the bypass diode may be applied outside of the sealant (150) as shown in FIGS. 13A and 13B. FIGS. 13A and 13B illustrate alternative arrangements of the diode (140) attachment to the link (120) by an electrical attachment, such as solder (145), adjacent to the lead wire (155) above the sealant (150).

As illustrated in FIGS. 14A and 14B, the photovoltaic module further includes a back box housing (165). Preferably, the housing (165) is formed as a single piece molded part, although it may be the combination of multiple molded pieces. The housing (165) is attached over the cut-out (110) thus protecting the bus element (115), links (120), lead wires (155) and diodes (140), if using, at their respective connections. The lead wires (155) also extend outside the housing (165). The cross-sectional view in FIG. 14B further illustrates potting material (170) that may be used to fill any cavities between the housing (165) and the other components of the back box. The housing (165) and potting material (170) may further serve to provide retention and strain relief for the lead wires (155).

The housing (165) may be produced by molding in a single-cavity flat parting-line mold with a single draft and no inserts as a low cost solution but could be more complex if needed. This manner of production would allow the housings (165) to be produced economically and may lead to cost reductions in producing the back box and may eliminate the need for a separate lid. Conventional back boxes are typically complex subassemblies incorporating one or more insert molded parts, grommets and fasteners and other parts, which not only increase cost and but also generally require a lid to complete the enclosure.

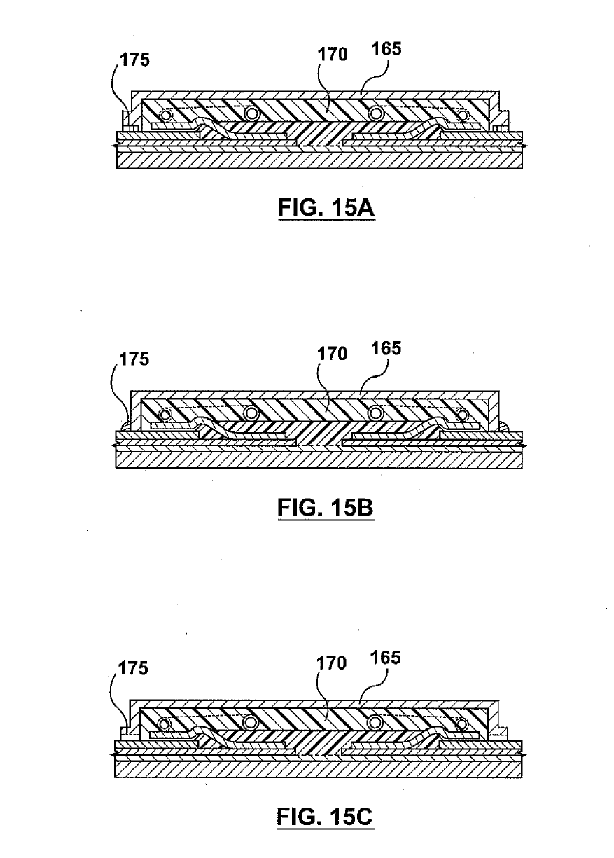

As shown in FIGS. 15A to 15C, the housing (165) may be further fastened and/or sealed to the back sheet (105) by a perimeter seal. FIGS. 15A to 15C illustrates some of the alternatives for a perimeter seal including using a seal or tacking adhesive (175) as shown in FIG. 15A, prior to placing the housing (165), and FIG. 15B, after placing the housing (165). Alternatively, a bonding tape (180) could be used as shown in FIG. 15C.

Preferably, the housing (165) may provide a large surface area (180) for a bond line and perimeter seal on all sides of the cut-out (110). The housing (165) may also provide a cosmetic finish for the module connections. The housing (165) may be configured to conceal any squash-out of the potting material (170) and/or secondary sealant (175). The housing (165) may further incorporate a labeling and/or marking area (not shown) suitable for either indelible printing and/or laser marking.

The housing (165) may also include relief features that assist with maintaining the planarity of the housing (165) relative to the photovoltaic module (100). These relief features may consist of posts, walls or other structure, which would bear against the back sheet (105) when the housing (165) is put in place.

The housing (165) may also incorporate perimeter relief features (not shown) that engage the perimeter of the cut-out (110) of the back sheet (105), which may improve resistance to lateral forces. This may have particular benefit when the back sheet (105) is made of glass or another thicker material.

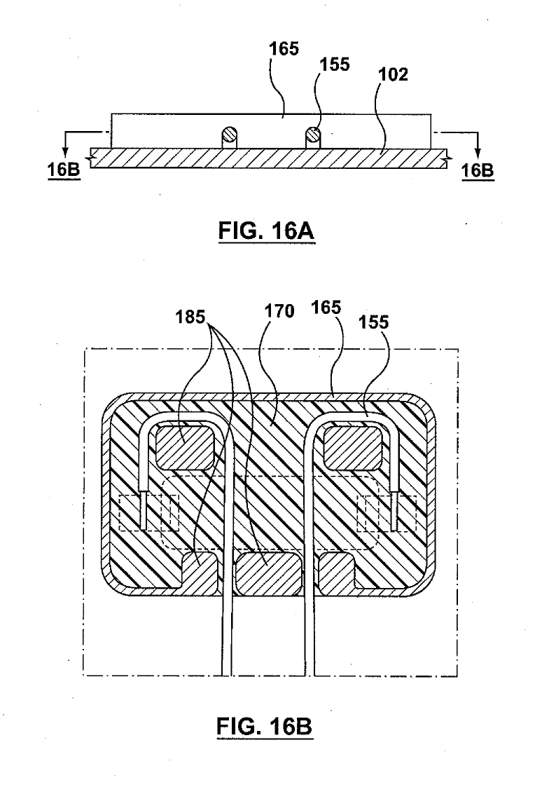

An example of the relief features incorporated in the housing (165) is shown in FIG. 16B as a trapping system (185). The trapping system (185) traps the convolutions of the formed lead wires (155) to provide reinforced strain relief. With the trapping system (185), retention does not depend solely on the strength of the potting material (170). As an example trapping system (185), posts, walls and other features, can be provided, which are configured to engage with contours of the lead wires (155) when the housing (165) is put into place. The trapping system (185) may assist with holding the lead wires (155) in position. The relief features and trapping system (185) may also allow for further bracing of the housing (165), while keeping the housing as low as possible. In particular, relief features and trapping system (185) may add more mechanical bracing to overcome load tests and/or gravity tests on the lead wires (155).

For assembly purposes, the housing (165) may be designed for automated bulk feeding systems. A plurality of the housings (165) may be bulk fed by various types of feeders including but not limited to vibratory, belt and step feeders (not shown). As the housings (165) may have a relatively simple shape and are unencumbered by attached lead wires or lids or other attachments the housings (165) should be compatible with most types of automatic feeders. Alternatively, the housings (165) may be fed on a tape backer using a conventional reel and feeding system. In another alternative, the housing (165) may be carried on an insert tape. Some feeding alternatives are described in concurrently filed U.S. patent application Ser. No. ______, claiming priority to U.S. Provisional Patent Application 61/319,725 filed Mar. 31, 2010, which is hereby incorporated herein by reference. As the housings (165) may not need to be trayed, kitted or manually fed, operator attendance should be reduced compared to conventional back box housing subassemblies.

The housings (165) may be made from an appropriate rated plastic suitable for the purposes of providing redundant electrical insulation. Additionally, the housings (165) could be insert molded or laminated with a metal or weather resistant product label. Alternatively, the housings (165) could be formed from cast or forged aluminum or similar weather resistant metal. If a metal housing is used a designated grounding point should be incorporated.

As discussed above, a potting material (170) is typically used to fill cavities between the back sheet (105), sealant (150), lead wires (155) and the housing (165). The potting material (170) may perform several functions including providing a secondary seal for the connections, electrical insulation, mechanical bonding of the housing (165) to the back sheet (105) and thermal management of the connections and diodes, if present.

The potting material (170) may be a reactive material that bonds to the back sheet (105) and to the housing (165). Alternatively, a dual-purpose potting material may be used as both a sealant and a potting. The potting material (170) may provide for orthogonal pull resistance of the back box. The use of the potting material (170) with the housing (165) may allow for better retention of the connections.

There may be a tradeoff between the liveliness and the durability of the potting material (170) and shear strength. It may also be preferable to add a perimeter seal (175) around the housing (165) using a sealing and bonding material, for example silicone or RTV, although other materials are contemplated. As an alternative, a common two-part weather sealing system could be used, which may consist of an interior butyl material and exterior silicone seal, which provides a useful combination of water and water vapor barrier properties.

Once the photovoltaic module (100) is completed, the potting material (170) and/or other sealant may require additional time to achieve full strength, in which case, a fast setting adhesive such as a multi-part epoxy, light tack adhesive, pressure sensitive adhesive in the form of a bead or tape may be used to create an immediate bond to provide sufficient adhesion to permit additional handling before the potting material (170) or the like have set. The housings (165) may be supplied with pressure sensitive tape or adhesive previously applied. Tape may also be supplied in previously die-cut form supplied in tape and reel format, on sheets or individually.

In the above described photovoltaic module, the cut-out (110) may be a small size because there is less need for tool entry via a back box assembly. There is no requirement for a larger back box which has room to allow for tool entry to make the lead wire connections. The housing (165), with the use of the sealant and the potting material, is intended to create a hermetic seal around the connections and protects the interior of the back-box. As the back box and connections are assembled directly to the photovoltaic module subassembly, visible inspection and/or electrical testing of the connections remains generally possible during the assembly process. Testing can occur at least until all of the electrical connections have been formed and until the primary seal has been formed.

The back box of the present embodiments is intended to be automation friendly as it uses part feeding (reels and spools) and not piece parts and is also intended to have a lower profile than conventional back boxes because tool access to attach the lead wires is not required, which allows for easier shipping with more weight per volume and lower back side clearances.

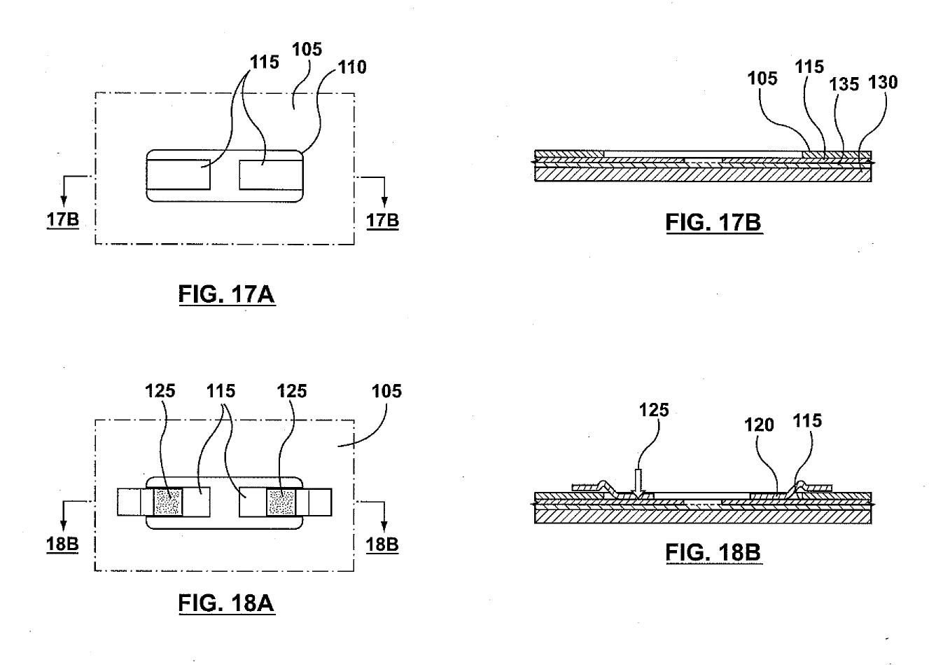

Having described the general structure of the photovoltaic module (100), FIGS. 17 to 22 illustrate an example of a sequence for assembling a back box on a back sheet of a photovoltaic module subassembly. In this example, only two bus element attachments are shown, which may be considered one of the simpler cases and is generally used in low wattage photovoltaic modules and thin-film solar modules.

FIGS. 17A and 17B illustrate the input received, which is generally a photovoltaic module subassembly. The photovoltaic module subassembly includes the back sheet (105) and the cut-out section (110) on the back sheet (105) such that the bus element (115) is exposed. It will be understood that the cut-out (110) may also be performed as a part of the present method. Kiss cutting, laser cutting and thermal cutting are some of the methods that have been applied to creating the openings in polymer back sheets following lamination. Generally, the application of heat may be required to facilitate peeling of the excised material.

First the links (120) are added, as illustrated in FIGS. 18A and 18B. The links (120) are first formed and excised from, for example, frame roll, typically by means of a single piece die set. The links (120) are then prepared for attachment to the bus element (115). Using soldering as an example, the links (120) are dipped into a flux film or solder paste film well. Then the links (120) are attached to the bus element (115) by means of, for example, thermode soldering. Alternatively, the links (120) may be attached by other methods including laser soldering, hot air jet or resistive soldering. Alternatively, attachment could be accomplished using a conductive adhesive (not shown).

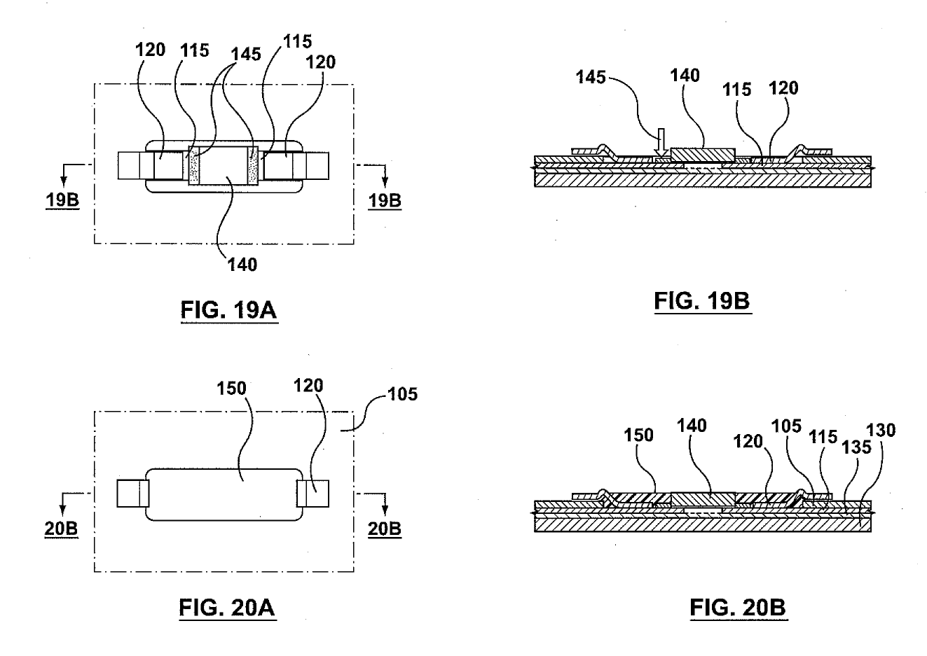

If the photovoltaic module is making use of one or more bypass diodes (140), the diodes can be added as illustrated in FIGS. 19A and 19B by attachment to the bus element (115), prior to or following the attaching of the links (120). The diodes (140) may be delivered by means of a tape and reel feeder. The diodes (140) are then prepared for soldering by dipping into a flux film or solder paste film well or by other means. The diodes (140) are then attached by, for example, thermode soldering or laser soldering. Alternatively, one or more axial diodes may be used as opposed to a bypass diode. The attachment method would be similar, although the diode may be picked from a feeder with an integral form and excise escapement or could be supplied with preformed leads on tape or tape & reel format.

After attaching the links (120) and diodes (140), if using an electrical test can be performed. The electrical test may include probing the links (120) and performing dark IV (current-voltage) or similar tests to confirm photovoltaic module subassembly (100) and link (120) integrity. If using diodes (140), the diodes (140) may also be tested at this stage.

Following the electrical test, if done, a sealant (150) may be applied to the cut-out (110) as shown in FIGS. 20A and 20B. Optionally, prior to applying the sealant, a primer (not shown) could be sprayed on the critical surfaces. A hot air blast or other drying means may be applied to dry the primer. The sealant (150) may then be dispensed from a volumetric dispensing system using, for example, at least one nozzle (not shown). After the sealant (150) is applied, a ultra-violet (UV) or infra-red (IR) lamp (not shown) may be used to set, cure, tack cure or skin out the sealant (150). Commonly, a saline solution or similar is used to activate surfaces to promote intimate contact and good adhesion of the sealants and/or adhesives.

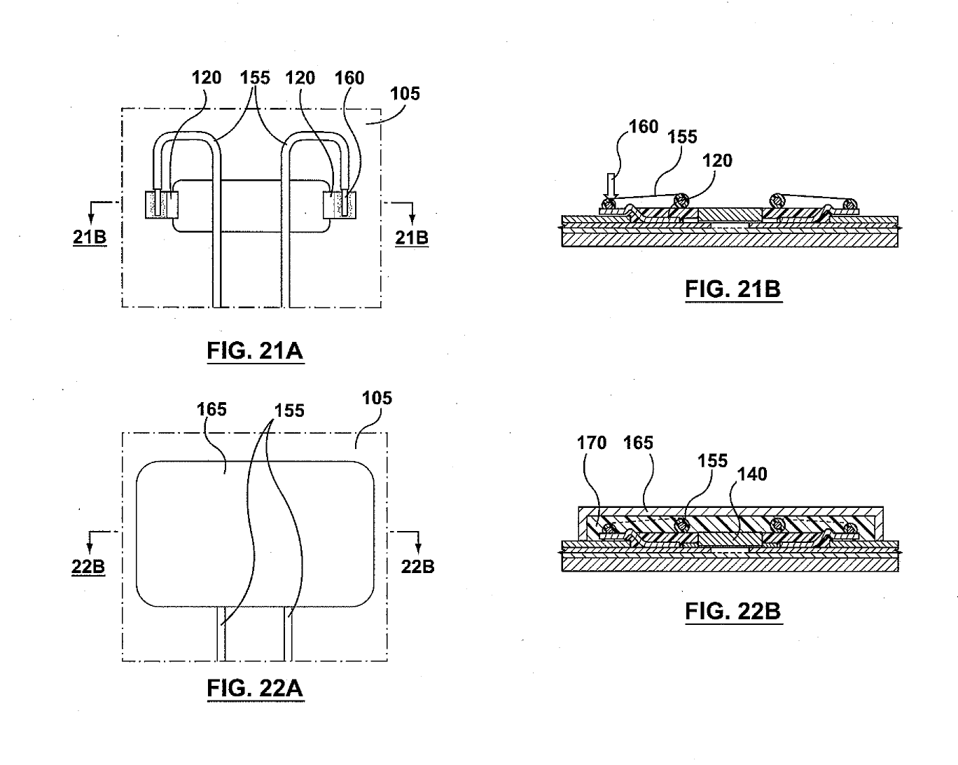

Once the sealant (150) has been applied, the lead wires (155) can be connected to the links (120), as illustrated in FIGS. 21A and 21B. The lead wires (155) may be stripped, which can be done by an escapement at the end of a wire feeder or by other means and may be cut and/or stripped to length using either the wire feeder or by other means. After the lead wires (155) are stripped they may be tinned by dipping the stripped ends into a solder well. Once tinned the lead wires (155) may be formed using a forming die or the like. The lead wires (155) may then be prepared for soldering by dipping them into a flux well or solder paste or by other means. The lead wires (155) will then be ready to be attached to the links by means of, for example, thermode soldering. Once attached, the lead wires (155) may be tacked into place by dispensing a tacking material onto the lead wires (155) and the back sheet (105) of the photovoltaic module. Other methods of soldering that may be used include laser soldering, hot air jet or resistive soldering. Alternatively, attachment could be accomplished using conductive adhesive. Alternatively, the lead wires (155) could be attached by means of spot welding or compression bonding.

Once the lead wires (155) are in place the housing (165) is applied, as illustrated in FIGS. 22A and 22B. The housing (165) may be provided by a bulk feeder (not shown). Optionally, a tacking adhesive (not shown) may be applied by dipping the housing (165) into a film dispenser or similar. The potting material (170) can be dispensed into the housing (165) by means of, for example, a volumetric dispensing system (not shown). Once the potting material (170) is dispensed the housing (165) may be pressed into place. A UV lamp (not shown) may be used to snap-cure the tacking adhesive if it was used. In alternate embodiments, the housing (165) may include an opening (not shown) to allow the potting material (170) to be inserted after the housing (165) is in place.

The potting (170) may be a hot-melt sealant reactive material, for example, a butyl compound, or a thermoset material, which is applied with a hot dispensing system. Alternatively, the potting material (170) may be a self-curing material, for example silicone, RTV or urethane, which can be applied by a one part or two-part mixing system. Additionally, a bead of sealant (not shown in FIGS. 22A and 22B) may be applied to the perimeter of the housing (165) after placement.

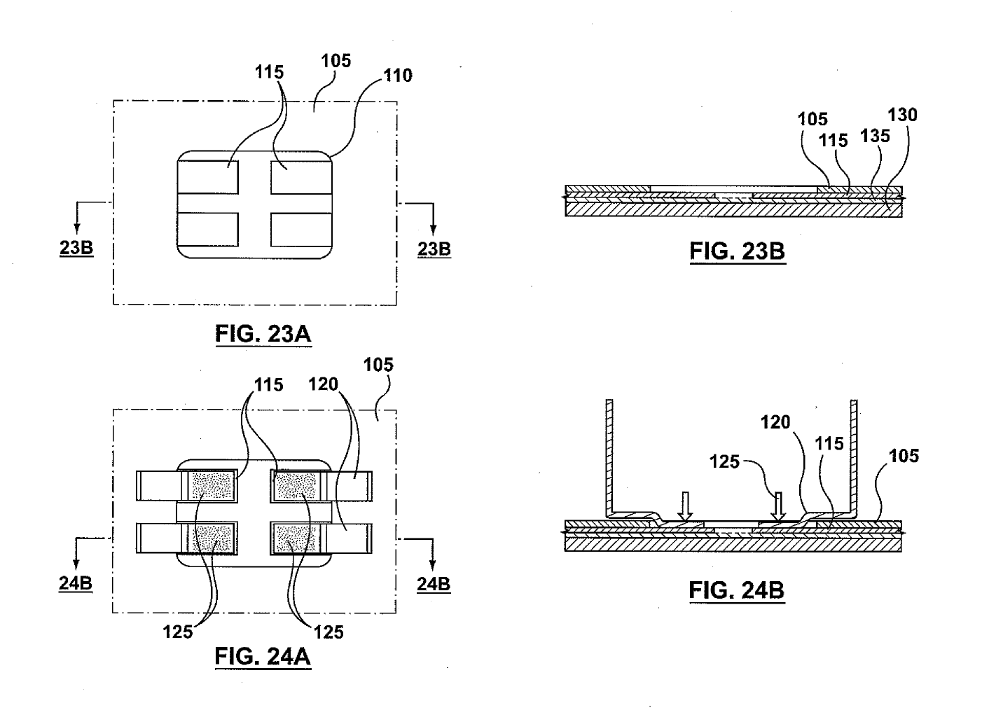

FIGS. 23 to 28 illustrate a second example of a sequence for assembling a photovoltaic module including a back box. As shown in FIGS. 23A and 23B, the photovoltaic module (100) subassembly includes the back sheet (105), the cut-out (110) and the exposed bus element (115). In this example, the photovoltaic module subassembly includes four bus elements (115) instead of two. This arrangement is a common example found in many larger conventional photovoltaic modules, particularly those with two or more cell strings. This particular configuration is found in modules with 4, 6 or 8 strings of cells; although, the function of the diodes may be different in various cases. A variation illustrated by this example is that the links are formed in two steps rather than one and may further provide a heat sink for the diodes, which, in this example, are attached directly to the links.

As shown in FIGS. 24A and 24B, first the links (120) are attached to the bus element (115). As shown in the cross section of FIG. 24B, the links (120) in this embodiment are formed to be longer for thermal management. As above, the links (120) are first formed and excised, typically be means of a single piece die set. The links (120) may then be attached by similar methods to those described above.

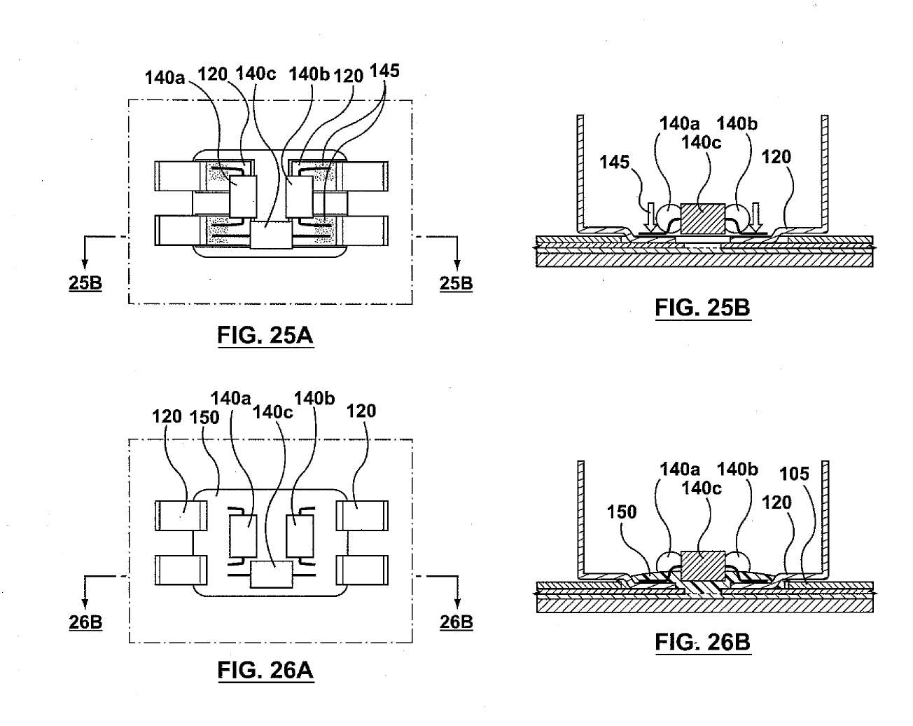

As shown in FIGS. 25A and 25B, the photovoltaic module may make use of a plurality of diodes (140) including bypass diodes (140a and 140b) and a blocking diode (140c). FIGS. 25A and 25B illustrate the diodes (140) as axial diodes, although surface mount diodes may be used as an alternative.

Following any electrical testing required, a sealant (150) may be applied as illustrated in FIGS. 26A and 26B. As in the example above, a primer could be sprayed prior to applying the sealant (150).

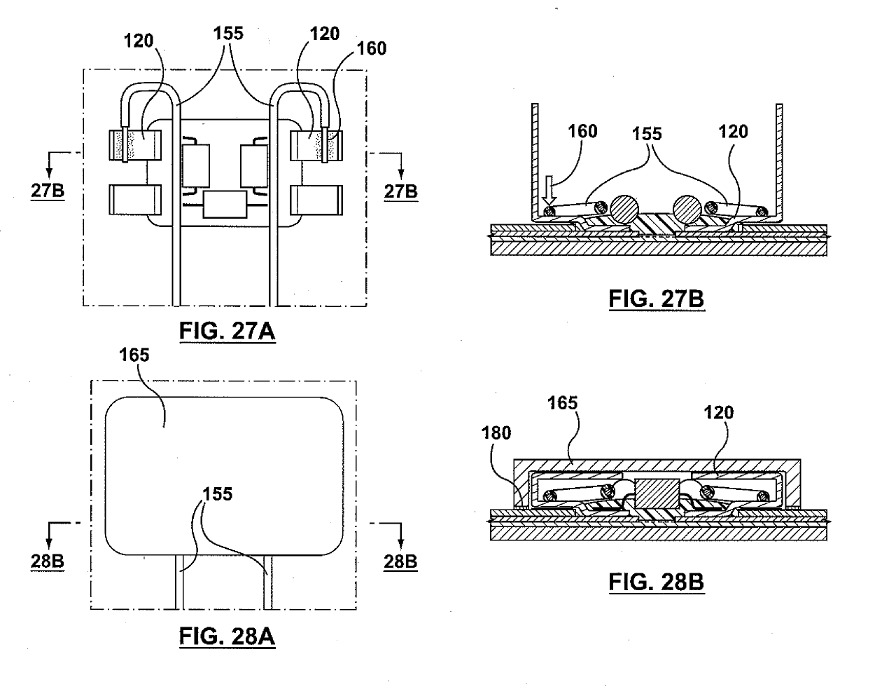

Once the sealant (150) has been set and/or cured, the lead wires (155) are connected to the links (120) as illustrated in FIGS. 27A and 27B. The lead wires (155) may be prepared and attached as described above.

Once the lead wires (155) are in place, a housing (165) is applied as shown in FIGS. 28A and 28B. As above, the housing (165) may be selected from a bulk feeder and the potting (170) can be dispensed into the housing (170) by means of a volumetric dispensing system.

The above examples are illustrative of possible assembly methods. It will be understood that the method may be varied to achieve similar results. For example, it may be possible to partially form links (120) prior to attaching them and then perform a secondary forming operation after applying the sealant (150). This variation may require the use of end-of arm tooling or the like.

As noted above, another option may be to place the housing (165) on the back sheet (105) prior to extruding the potting (170). The potting (170) may then be added into the housing (165) through at least one aperture provided in the housing (165). Also, a secondary seal may also be added by extruding sealing material (not shown) through the aperture provided in the housing (165). It may also be possible to dispense the potting (170) directly onto the photovoltaic module prior to applying the housing (165).

If desired, module functional testing (IV testing) may be performed prior to applying the housing (165). Testing performed at this time may allow for easier probing and the results of the testing may be marked on the housing (165) prior to assembly, which may avoid a separate marking step.

The above-described embodiments are intended to be examples only. Alterations, modifications and variations can be effected to the particular embodiments by those of skill in the art without departing from the scope of this application. In the preceding description, for purposes of explanation, numerous details are set forth in order to provide a thorough understanding of the embodiments. However, it will be apparent to one skilled in the art that these specific details may not be required in order to practice the embodiments. In other instances, well-known structures, equipment and the like may not be shown or only be shown in block diagram form in order not to obscure the embodiments.

We claim:

1. A method for assembling a photovoltaic module with an integrated back box comprising:
applying links to a back side of a photovoltaic module subassembly;
forming a connection between the links and an internal bus element of the photovoltaic sub-assembly;
connecting external lead wires to the links;
applying a housing over the links and a portion of the lead wires; and
applying potting material to fill any cavities between the back of photovoltaic module, the lead wires and the housing.

2. The method of claim 1 further comprising applying a sealant over the links.

3. The method of claim 1 further comprising connecting diodes to the photovoltaic module subassembly.

4. The method of claim 1 wherein the lead wires are configured to be fed, trimmed, formed, and soldered in play by automation tooling.

5. The method of claim 1 wherein the housings are configured to be fed on a tape backer.

6. The method of claim 5 wherein the housings are fed using a conventional tape and reel feeding system.

7. The method of claim 1 wherein the housings are configured to be fed on an insert tape wherein the insert tape includes an insert that is part of the housing.

8. A photovoltaic module with integrated back box comprising:
a photovoltaic module sub-assembly comprising:
a back sheet;
a cut-out in the back sheet; and
a bus element exposed via the cut-out;
a link bonded to the bus element and extends external to the cut-out;
a lead wire bonded to the link; and
a housing attached to the back sheet and configured to cover the cut-out, bus element and link wherein the lead wire extends from inside the housing to outside the housing and wherein the housing is attached to the back sheet after the wire is bonded to the link.

9. The photovoltaic module of claim 8 wherein the link connecting the bus element to the lead wire is a flexible link.

10. The photovoltaic module of claim 8 further comprising a sealant for sealing the cut-out.

11. The photovoltaic module of claim 8 wherein the housing comprises a trapping system.

12. The photovoltaic module of claim 11 wherein the trapping system comprises support members configured to support and brace the lead wires

13. A method for assembling a photovoltaic module with integrated back box including:
receiving a photovoltaic module sub-assembly wherein the photovoltaic module sub-assemble comprises:
a back sheet;
a cut-out in the back sheet; and
a bus element exposed via the cut-out;
connecting a link to the bus element such that the link extends external to the cut-out;
bonding a lead wire to the link; and
attaching a housing to the back sheet such that the housing covers the cut-out, the link and the bus element, wherein the lead wire extends from inside the housing to outside the housing.

14. The method in claim 13 further comprising applying a sealant to cover the cut-out and the bus element prior to attaching the lead wire to the link.

15. The method of claim 14 further comprising applying the sealant around a point where the lead wires extends outside the housing.

15. The method of claim 13 further comprising attaching a diode to the bus element prior to attaching the housing to the back sheet.

17. The method of claim 13 wherein attaching the housing to the back sheet includes applying an adhesive tape to the housing and pressing the housing onto the back sheet.
